(19) United States
(12) Patent Application Publication
(10) Pub. No.: US 2011/0263057 A1
(43) Pub. Date: Oct. 27, 2011

(54) Active Array Substrate, Liquid Crystal Display Panel, and Manufacturing Method Thereof

(75) Inventors: Yen-Heng Huang, Hsinchu (TW); Chung-Kai Chen, Hsinchu (TW); Shu-Chin Lee, Hsinchu (TW)

(73) Assignee: AU OPTRONICS CORP., Hsinchu (TW)

(21) Appl. No.: 13/176,958

(22) Filed: Jul. 6, 2011

Related U.S. Application Data
(62) Division of application No. 12/133,777, filed on Jun. 5, 2008, now abandoned.

(30) Foreign Application Priority Data
Feb. 4, 2008 (TW) 097104179

(51) Int. Cl. H01L 33/58

(52) U.S. Cl. 438/30; 438/29; 257/E33.067

(57) ABSTRACT

An active array substrate, liquid crystal display panel, and manufacturing method thereof are provided. The active array substrate includes a base, a plurality of scan lines disposed on the base, a plurality of data lines perpendicular to the scan lines, a plurality of pixel electrodes, a plurality of active devices, in which each active device is connected to the corresponding scan line, data line and pixel electrode to form a pixel region. The height adjust structure, disposed on the active device, the data line or the scan line, can be shaped into a circle, circle-like shape, ellipse, a compact pattern without any acute angle or a compact pattern without any right angle.

### CROSS-REFERENCES TO RELATED APPLICATIONS

The present application is a divisional application of U.S. patent application Ser. No. 12/133,777 filed on Jun. 5, 2008, which claims the benefit from the priority of Taiwan Patent Application No. 097104179, filed on Feb. 4, 2008, the disclosure of which are incorporated by reference herein in their entirety.

### BACKGROUND OF THE INVENTION

1. Field of the Invention

The present invention generally relates to an active array substrate, a liquid crystal display panel and method for manufacturing the same; and particularly relates to an active array substrate having a color filter and method for manufacturing the same.

2. Descriptions of the Related Art

Conventional methods for manufacturing color filters use three color resists and three photolithography processes. The three color resists are sequentially formed in the pixel regions of a substrate to form a color filter. Because the color resists layers are formed by dropping the color resist liquid on the substrate and then performing spin coating, most color resists are wasted when conducting the spin coating process. Therefore, the method is costly due to the high price of the color resist. Furthermore, many organic solutions have to be used for the photolithography process, which pollutes the environment.

Recently, a method for manufacturing a color filter by ink jet printing (IJP) has been developed. With IJP, three color materials can be printed simultaneously in the pixel regions. Compared with the conventional methods, the processing costs and raw materials can be saved. Therefore, IJP can be applied for large size display panels.

A method for integrating the color filter and active array substrate by IJP follows.

U.S. Pat. No. 5,919,532 discloses a method for manufacturing an active array substrate comprising the following steps: forming the organic resin composition on the substrate with a thin film transistor formed thereon and curing the organic resin composition by heating; forming a photoresist thereon and exposing the photoresist with a mask; patterning the resin by etching process to form a contact hole for electrically connecting a pixel electrode with a thin film transistor; forming red, green and blue inks using the IJP in predetermined regions defined by the patterned resin. As a result, an active array substrate with a color filter is substantially completed.

### SUMMARY OF THE INVENTION

Accordingly, the present invention is directed to provide an active array substrate. The active array substrate is a color filter on an array substrate (COA).

The present invention is directed to a method for manufacturing an active array substrate to solve the problem of using too many masks in the conventional method.

The present invention is directed to a method for manufacturing an active array substrate to increase the efficiency of the panel and decrease costs.

The present invention is directed to a method for manufacturing an active array substrate. The photoresist in the earlier steps of the process is served as the banks for the later IJP process, thereby reducing the process steps.

The present invention is directed to a method for manufacturing an active array substrate. The active array substrate comprises a height auxiliary structure formed by the UP process to achieve the effect of hybrid spacers.

In one embodiment of the present invention, the active array substrate includes a base; a plurality of scan lines disposed on the base; a plurality of data lines disposed perpendicular to the scan lines; a plurality of pixel electrodes; a plurality of active devices, with each of the active devices electrically connected with the corresponding scan line, data line and pixel electrode to form a pixel region; and a height auxiliary structure, substantially disposed on the active device, the data line or the scan line, wherein the top view of the height auxiliary structure is in the shape of a circle, circle-like or an irregular compact pattern.

In one embodiment of the present invention, the aforesaid active array substrate further includes at least one color filter layer disposed on the base and substantially in the pixel region.

In one embodiment of the present invention, the aforesaid liquid crystal display panel includes the aforesaid active array substrate; an opposite substrate disposed opposite to the active array substrate; a plurality of spacers disposed between the active array substrate and the opposite substrate, wherein at least one of the spacers and the height auxiliary structure overlap; and a liquid crystal layer disposed between the active array substrate and the opposite substrate.

In one embodiment of the present invention, the method for manufacturing an active array substrate includes the following steps: providing a base; forming a scan line, a data line and an active device on the base; forming a photoresist layer on the scan line, the data line and the active device; patterning the photoresist layer to form at least one patterned bank, wherein the one patterned bank forms at least one pixel region; providing fluid color material in the pixel region; curing the fluid color material to form a plurality of color filter layers; and forming a pixel electrode electrically connected with the active device and is disposed in the pixel region.

In one embodiment of the present invention, the step of patterning the photoresist layer in the aforesaid method for manufacturing the active array substrate comprises the following steps: providing a mask over the photoresist layer; exposing and the photoresist layer by the mask; removing a portion of the photoresist layer to form the at least one patterned bank; and etching the passivation to form a contact hole, wherein the pixel electrode is electrically connected with the active device via the contact hole.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

The accompanying drawings are included to provide a further understanding of the invention, and are incorporated in and constitute a part of this specification. The drawings illustrate the embodiments of the invention and, together with the description, serve to explain the principles of the invention.

FIG. 1 is a top view of the active array substrate of the present invention.

FIGS. 2(a) to 2(f) are cross sectional views schematically showing a manufacturing method for manufacturing the active array substrate according to the first embodiment of the present invention.

FIGS. 3(a) to 3(h) are cross sectional views schematically showing a manufacturing method for manufacturing the active array substrate according to the second embodiment of the present invention.

FIGS. 4(a) to 4(f) are cross sectional views schematically showing a manufacturing method for manufacturing the active array substrate according to the third embodiment of the present invention.

FIGS. 5(a) to 5(g) are cross sectional views schematically showing a manufacturing method for manufacturing the active array substrate according to the fourth embodiment of the present invention.

FIG. 6 is an exploded view of the liquid crystal display panel according to the present invention.

FIGS. 7(a) to 7(d) are top views of the height auxiliary structures according to the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings with the descriptions referring to the same or like parts.

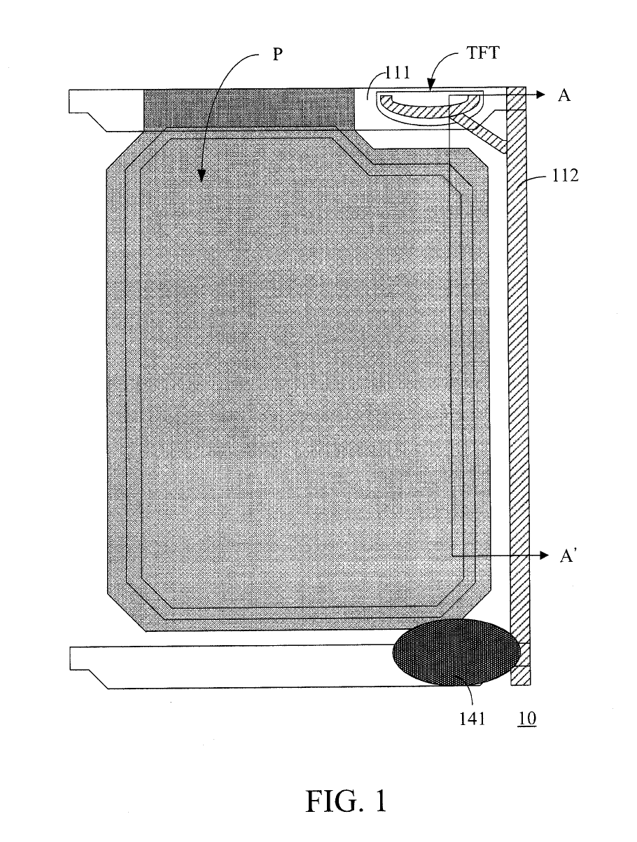

FIG. 1 is a top view of an active array substrate 10. For clear illustration, the height auxiliary structure 141 on the thin film transistor TFT in the following embodiments is not shown in FIG. 1. The active array substrate 10 comprises a base 110, a plurality of scan lines 111 disposed on the base 110, a plurality of data lines 112 disposed perpendicular to the scan lines 111, a plurality of pixel electrodes 150 and a plurality of active devices TFT. Each of the active devices TFT are electrically connected with the corresponding scan line 111, data line 112 and pixel electrode 150 to form a pixel region P. For convenience, FIG. 1 only shows one scan line 111, one data line 112, one pixel electrode 150 and an active device TFT.

The following embodiments include the method for manufacturing the active array substrate 10 corresponding to the section line AA′ shown in FIG. 1 and the cross sectional view of the structure corresponding to the method thereof. The detailed structures and process corresponding to the method for manufacturing the active array substrate 10 is set forth in the following description.

### First Embodiment

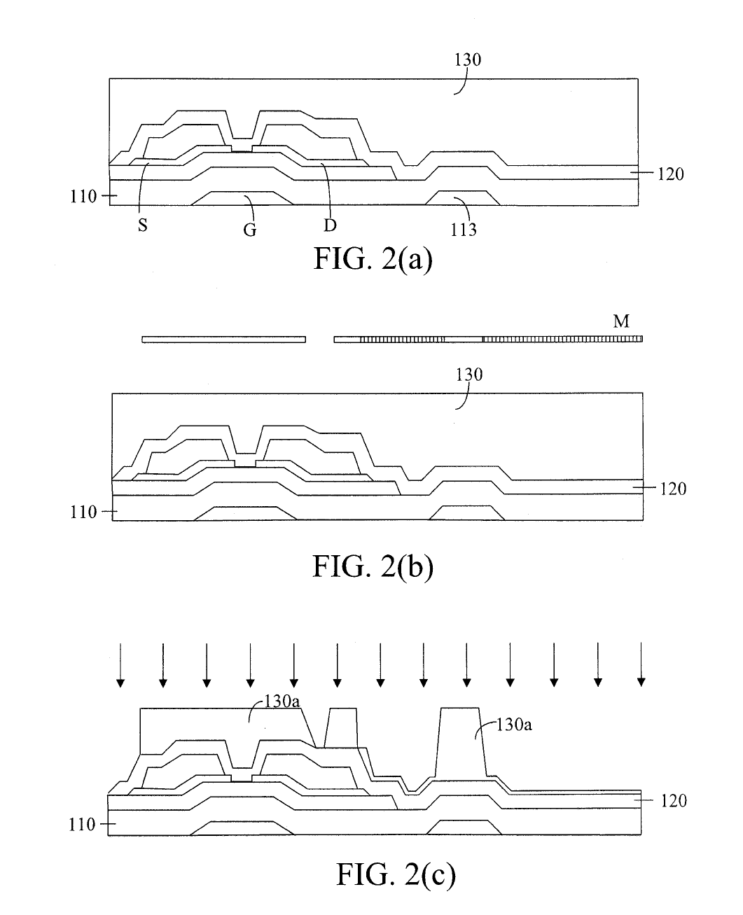

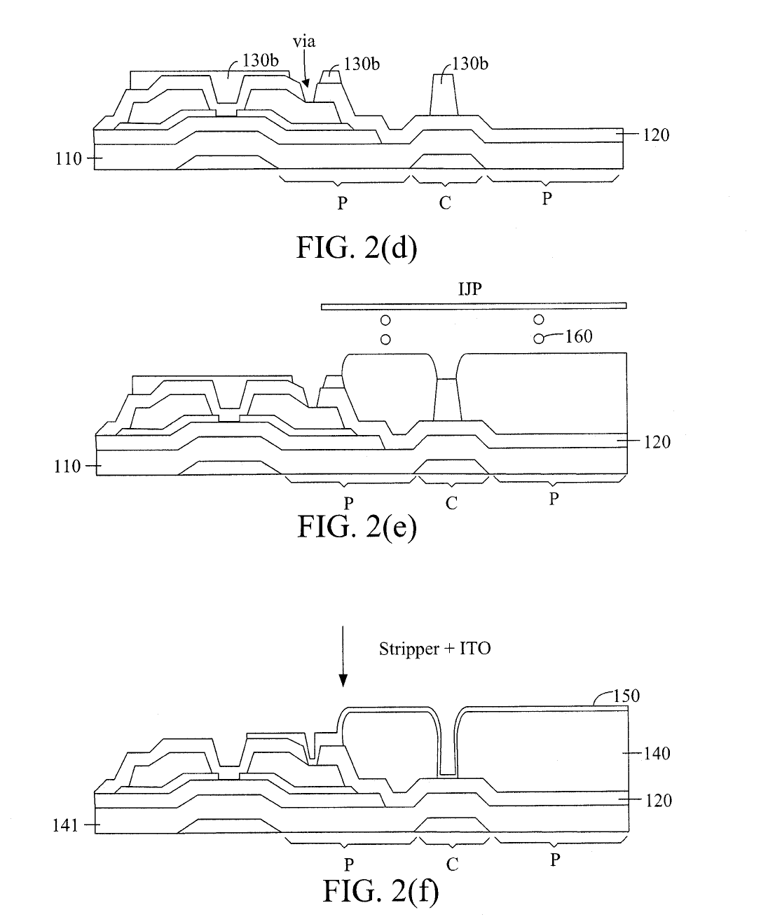

FIGS. 2(a) to 2(f) are cross sectional views schematically showing a manufacturing method for manufacturing the active array substrate 10 according to the first embodiment of the present invention.

As shown in FIG. 2(a), the base 110 is first provided, followed by forming the scan line 111, capacitor electrode 113, data line 112, active device (ex. thin film transistor TFT) and passivation 120 on the base 110. The thin film transistor TFT comprises a gate G, a source S and a drain D. Then, a photoresist layer 130 is formed, which completely covers the passivation 120. The photoresist layer 130 has an average thickness of about 0.5 micrometers to 5 micrometers.

Next, as shown in FIG. 2(b), provide a mask M above the photoresist layer 130. Mask M may be a half-tone mask or a grey-tone mask for example. The effect of the half-tone mask or grey-tone mask is understood by those skilled in the art and will not be discussed in detail herein. The photoresist layer is exposed 130 by using the mask M. Then, as shown in FIG. 2(c), the photoresist layer 130 is developed by removing at least a portion of the photoresist layer 130 to form at least one patterned bank 130a. Next, as shown in FIG. 2(d), at least a portion of the patterned bank 130a is removed and etched into the passivation 120 to form the patterned bank 130b and contact hole Via. The removal of the portion of the patterned bank 130a and etching of the passivation 120 may be completed with only one step. In other words, the photoresist layer 130 can be defined into at least one patterned bank 130a, and then the contact hole Via can be formed by etching with either the etching gas or etching liquid. However, the step of removing at least a portion of the patterned bank 130a and etching the passivation 120 may include two sub-steps. In other words, the patterned bank 130a would first be formed by patterning the photoresist layer 130, and then removing at least one portion of the patterned bank 130a to form the patterned bank 130b. Thereafter, the contact hole Via is formed by using at least one etching gas or etching liquid to etch the passivation 120, as shown in FIG. 2(d). Therefore, a pixel region P and a capacitor region C are defined.

Then, as shown in FIG. 2(e), a fluid color material 160 is provided in the pixel region P within the patterned bank 130b by an ink jet printing process (IJP). The fluid color material 160, for example, may be thermal sensitive or photo sensitive. Fluid color material 160, for example, may be a dye, a pigment or a combination thereof. The color of the fluid color material 160, for example, may be red, green and blue (RGB), white, red, green and blue (WRGB) or red, green, blue, cyan, magenta, and yellow (RGBCMY). Next, the fluid color material 160 cures to form a plurality of color filter layers 140, whose color may be red, green or blue. At least one portion of the patterned bank 130b is removed to define a capacitor region C. The patterned bank 130b on the thin film transistor TFT can also be removed simultaneously.

Finally, as shown in FIG. 2(f), a pixel electrode 150 is formed on the color filter layers 140. The pixel electrode 150 is electrically connected with the drain D of the thin film transistor TFT through the contact hole Via and is disposed in the pixel region P accordingly. The pixel electrode 150 may be formed with a transparent conductive layer on the color filter layers 140. The transparent conductive layer, for example, may be ITO or IZO. Then, the transparent conductive layer is patterned to form the pixel electrode 150. The step of patterning the transparent conductive layer may use photolithography or laser ablation. The pixel electrode 150 and the capacitor electrode 113 form a storage capacitor.

As a result, the active array substrate 10 of the present embodiment is completed. In FIG. 1 and FIG. 2(f), the active array substrate 10 of the present embodiment comprises a base 110, a scan line 111, a capacitor electrode 113, a data line 112, a thin film transistor TFT and a passivation 120 on the base 110. The color filter layers 140 are disposed in the pixel regions P. The pixel electrode 150 is disposed on the color filter layers 140. The pixel electrode 150 is electrically connected with the drain D of the thin film transistor TFT via the contact hole Via and is disposed in the pixel region P accordingly. The pixel electrode 150 and capacitor electrode 113 form the storage capacitor.

An advantage of the present embodiment is that the photoresist layer 130 is directly used and serves as the bank for providing fluid color material 160 in the IJP process, so the process can be easier.

### Second Embodiment

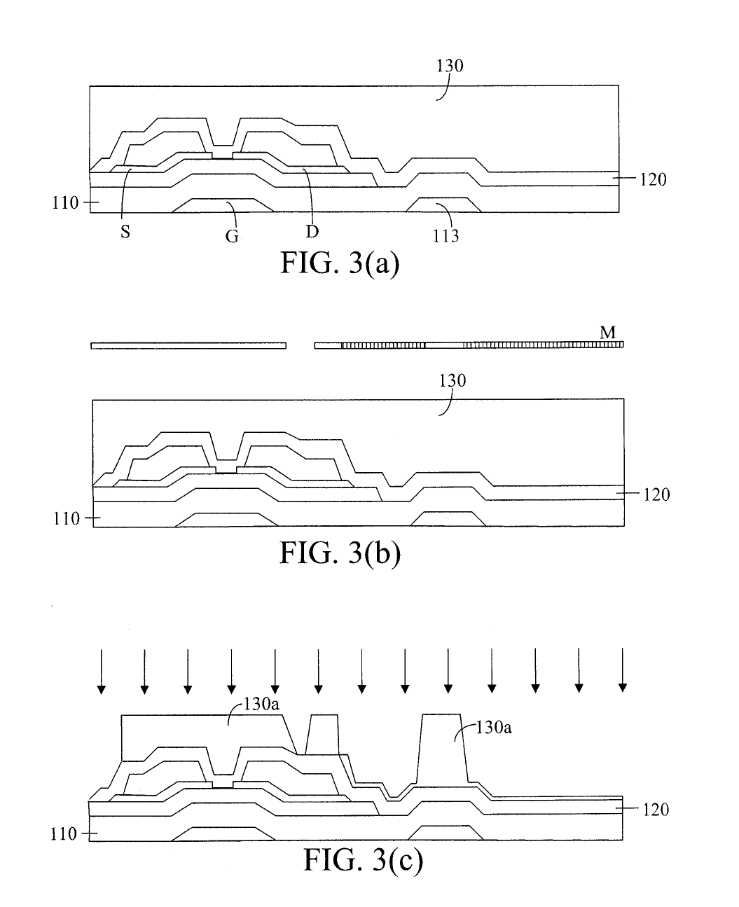

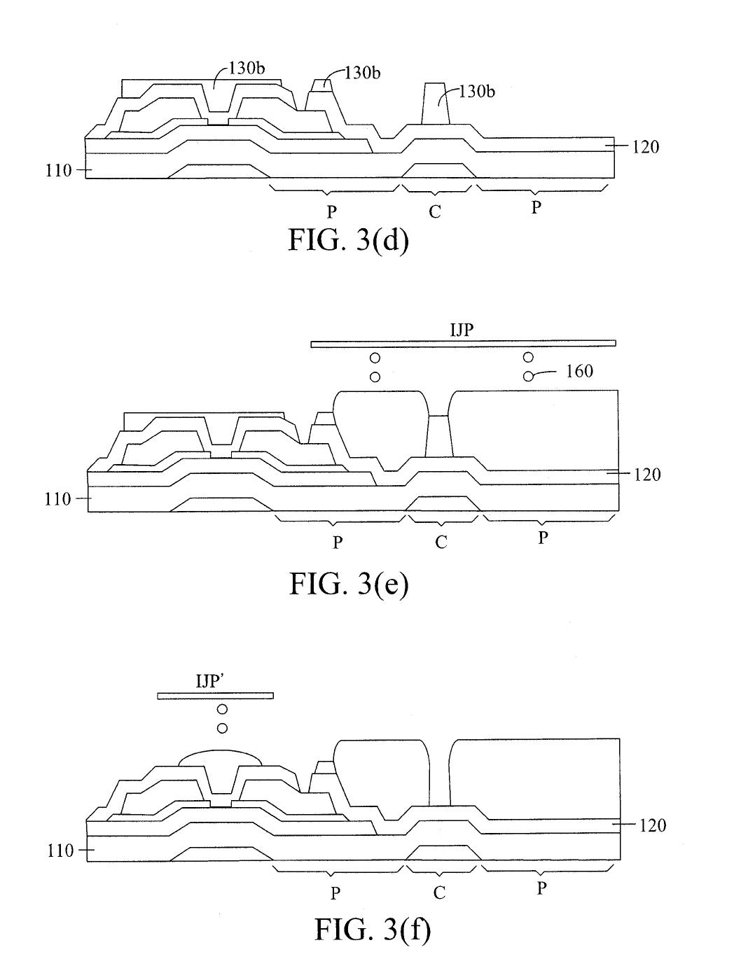

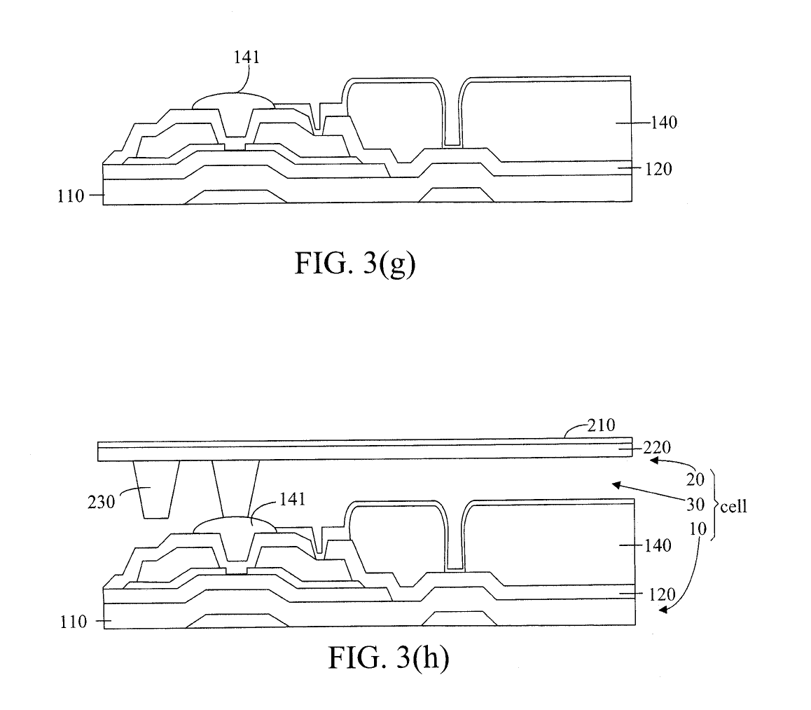

FIGS. 3(a) to 3(g) are cross sectional views schematically showing a manufacturing method for manufacturing the active array substrate 10 according to the second embodiment of the present invention. Because FIGS. 3(a) to 3(g) are corresponding to the same manufacturing process as that of FIGS. 2(a) to 2(e), the reference number of the elements will continue to be used and the details will not be further described herein.

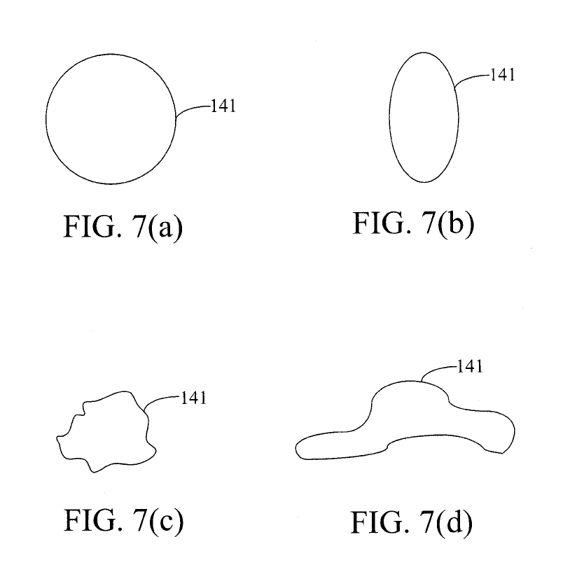

In FIG. 3(1), after curing the fluid color material 160 to form the color filter layers 140 and removing at least one portion of the patterned bank 130b, the fluid color material 160 is provided, which may be red, red or blue, on the thin film transistor TFT by ink jet printing IJP′ for the height auxiliary structure 141 which will be formed in later steps. Then, the fluid color material 160 is cured on the thin film transistor TFT to form the height auxiliary structure 141. Because the height auxiliary structure 141 is formed by the ink jet printing IJP′, the top view of the height auxiliary structure 141 has a circle shape, a circle-like shape or an irregular compact pattern as shown in FIGS. 7(a) to 7(d). The height auxiliary structure 141 has an average thickness of about 0.01 micrometer to 2 micrometers. The height auxiliary structure 141 has an average width of about 1 micrometer to 100 micrometers. The material of the height auxiliary structure 141 is thermal sensitive or photosensitive. The height auxiliary structure 141 is comprised of dye, pigment or a combination thereof. The height auxiliary structure 141 can be disposed on or straight on the thin film transistor TFT. However, depending on the design or demand, the height auxiliary structure 141 can be disposed on, and preferably aligned with the data line 112, the scan line 111 or in the pixel regions P.

It should be emphasized that the ink jet printing IJP′ for the color filter layers 140 and ink jet printing IJP for the height auxiliary structure 141 can be integrated into a single step. That is to say, in FIG. 3(e), the fluid color material 160 is provided to both the pixel region P and the patterned bank 130b on the thin film transistor TFT, so after curing the fluid color material 160 and removing at least a portion of the patterned bank 130b, a few of the un-removed patterned banks 130b would exist between the height auxiliary structure 141 and the thin film transistor TFT. The color of the height auxiliary structure 141 and that of the color filter layers 140 can be the same or different.

Then, in FIG. 3(g), form the pixel electrode 150 on the color filter layers 140. The step can refer to FIG. 2(f) and the description thereof in the first embodiment.

Finally, an opposite substrate 20 is provided, as shown in FIG. 3(h). The opposite substrate 20 may comprise a plurality of spacers 230. At least one of the spacers 230 is overlapped with at least one part of the height auxiliary structure 141 or completely on the height auxiliary structure 141. A liquid crystal layer 30 is formed between the active array substrate 10 and the opposite substrate 20 by one drop fill (ODF) or injection. The opposite substrate 20 comprises a base 210 and a common electrode 220 on the base 210. The sizes of the spacers 230 may be the same. The spacers 230 may be photo spacers, and the shape thereof may be post or ball. As a result, a liquid crystal display panel Cell is completed.

As a result, the liquid crystal display panel Cell of the present embodiment comprises the base 110, the scan line 111, the capacitor 113, the data line 112, the thin film transistor TFT and the passivation 120 on the base 110. The color filter layers 140 are in the pixel regions P. The pixel electrode 150 is disposed on the color filter layers 140. The pixel electrode 150 is electrically connected with the drain D of the thin film transistor TFT via the contact hole Via and is disposed in the pixel region P correspondingly. The pixel electrode 150 and the capacitor electrode 113 together form a storage capacitor. The height auxiliary structure 141 is formed on the thin film transistor TFT. The top view of the height auxiliary structure 141 has a circle, a circle-like shape or an irregular compact pattern. The irregular compact pattern may be an irregular compact pattern without any acute angle or an irregular compact pattern without any right angle. The height auxiliary structure 141 has an average thickness of about 0.01 micrometer to 2 micrometers. The height auxiliary structure 141 has an average width of about 1 micrometer to 100 micrometers. The material of the height auxiliary structure 141 includes a thermal sensitive or photosensitive material. The material of the height auxiliary structure 141 comprises a dye, pigment or a combination thereof. The opposite substrate 20 may comprises a plurality of spacers 230. At least one of the spacers 230 is overlapped with at least one part of the height auxiliary structure 141 or completely on the height auxiliary structure 141. The liquid crystal layer 30 is formed between the active array substrate 10 and the opposite substrate 20. The opposite substrate 20 comprises the base 210 and the common electrode 220 on the base 210. The height auxiliary structure 141 can be disposed on or straight on the thin film transistor TFT. However, depending on the design or demand, the height auxiliary structure 141 can be disposed on, and preferably aligned with the data line 112, the scan line 111 or in the pixel regions P.

### Third Embodiment

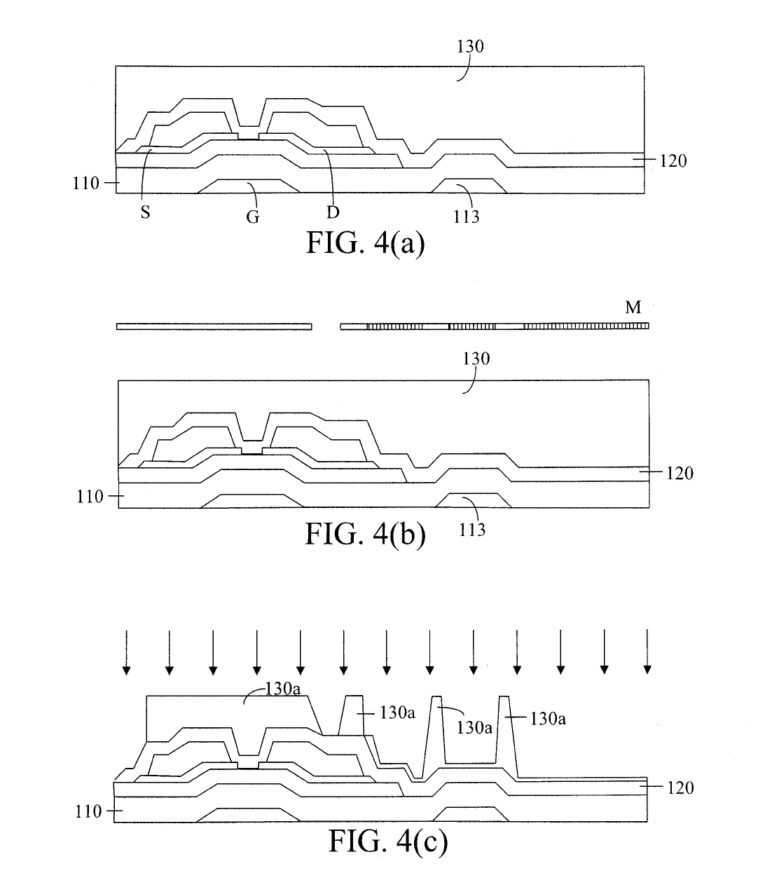

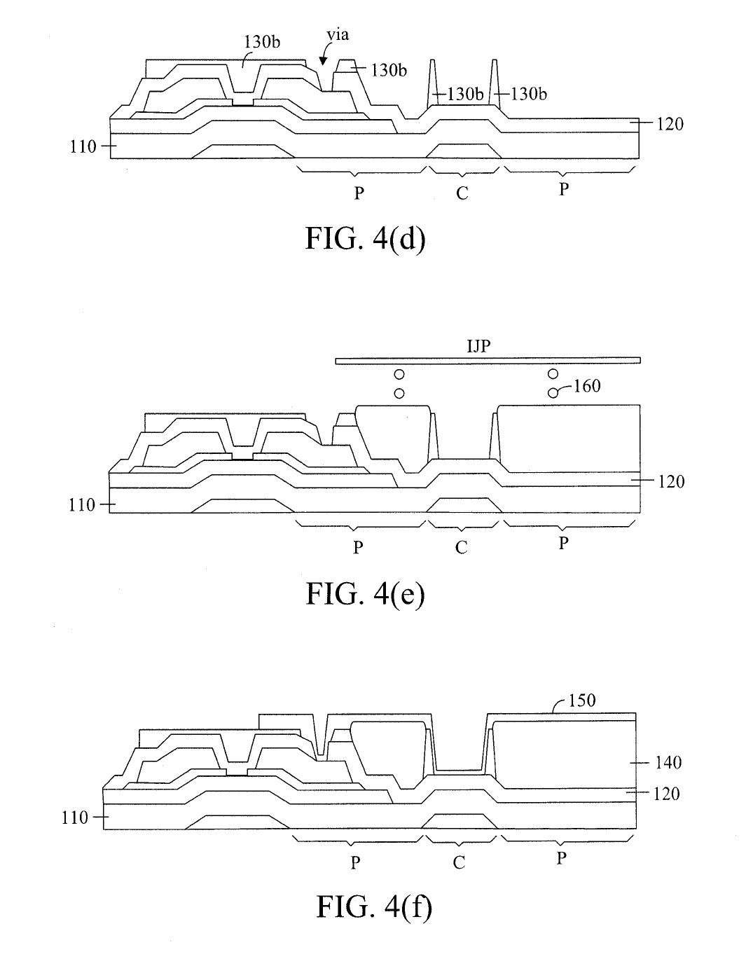

FIGS. 4(a) to 4(f) are cross sectional views schematically showing a manufacturing method for manufacturing the active array substrate 10 according to the third embodiment of the present invention.

FIGS. 4(a)-4(b) and description thereof are the same as that of FIGS. 2(a)-2(b), so detailed descriptions are omitted for convenience herein.

As shown in FIG. 4(c) the pattern of the patterned bank 130a is unlike FIG. 2(c). In the present embodiment, the capacitor region C is pre-defined.

Next, as shown in FIG. 4(e), the fluid color material 160 is provided by the ink jet printing IJP in the pixel region P defined within the patterned bank 130b. The fluid color material 160 is, for example, a dye, pigment or a combination thereof. The color of the fluid color material 160 is, for example, red, green or blue. Next, the fluid color material 160 is cured to form a plurality of the color filter layers 140.

Finally, as shown in FIG. 4(f), a pixel electrode 150 is formed on the color filter layers 140. The pixel electrode 150 is electrically connected with the drain D of the thin film transistor TFT through the contact hole Via and is disposed in the pixel region P accordingly. The pixel electrode 150 may be formed with a transparent conductive layer on the color filter layers 140. The transparent conductive layer is, for example, ITO or IZO. Then, the transparent conductive layer is formed on the pixel electrode 150. The transparent conductive layer may be patterned using photolithography or laser ablation. The pixel electrode 150 and the capacitor electrode 113 together form a storage capacitor.

Because the patterned bank 130b is not removed, at least a portion of the pixel electrode 150 remains on the patterned bank 130b.

As a result, the active array substrate 10 of the present embodiment is completed. As shown in FIGS. 1 and 4(f), the active array substrate 10 of the present embodiment comprises the base 110, the scan line 111, the capacitor electrode 113, the data line 112, the thin film transistor TFT and the passivation 120 on the base 110. The color filter layers 140 are in the pixel regions P. The pixel electrode 150 is disposed on the color filter layers 140. The pixel electrode 150 is electrically connected with the drain D of the thin film transistor TFT via the contact hole Via and is disposed in the pixel region P accordingly. The pixel electrode 150 and the capacitor electrode 113 form a storage capacitor. Specifically, unlike the first embodiment, the patterned banks 130b remain, so the step of removing the patterned banks 130b is reduced.

### Fourth Embodiment

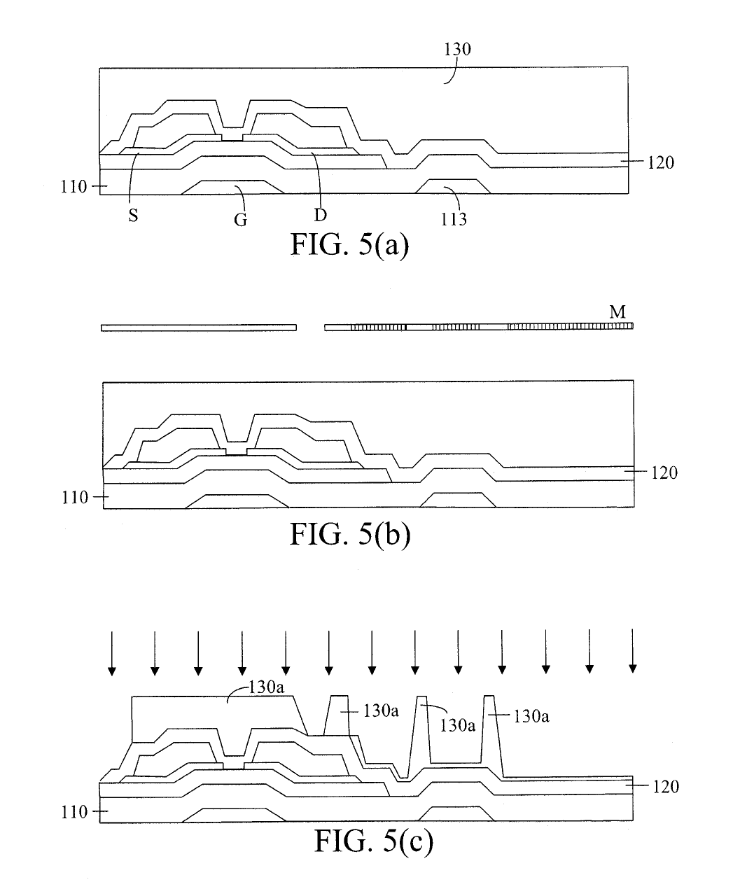

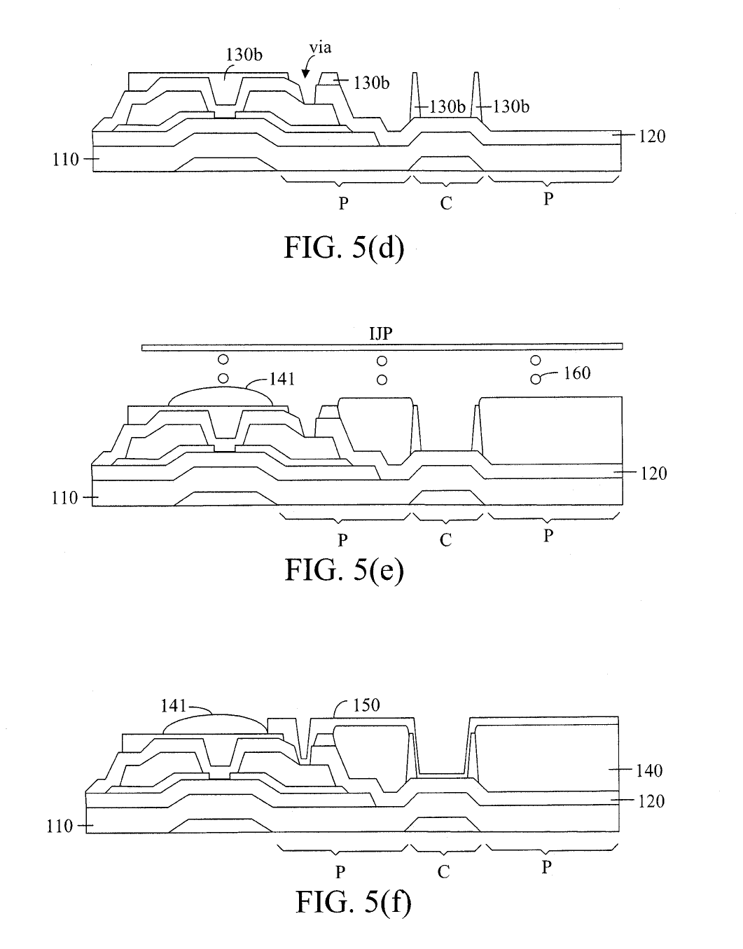

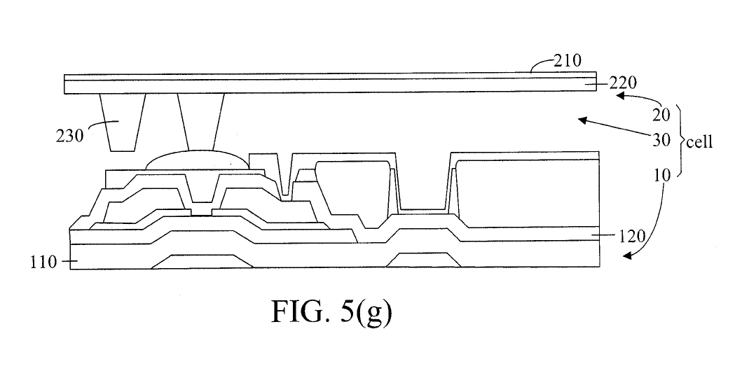

FIGS. 5(a) to 5(g) are cross sectional views schematically showing a manufacturing method for manufacturing the active array substrate 10 according to the fourth embodiment of the present invention. FIGS. 5(a) to 5(d) and description thereof are the same as that of FIGS. 4(a) to 4(d) of the third embodiment. Therefore, the detailed descriptions of FIGS. 5(a) to 5(d) are omitted.

In FIG. 5(e), the fluid color material 160 is provided, which may be red, green or blue, in the pixel region P defined within the patterned banks 130b and on the thin film transistor TFT. A few patterned banks 130b remains between the fluid color material 160 on the thin film transistor TFT and the thin film transistor TFT. Next, the fluid color material 160 is cured to simultaneously form the color filter layers 140 and height auxiliary structures 141. The color of the height auxiliary structures 141 may be the same as or different from that of the color filter layers 140.

Thereafter, FIGS. 5(f) to 5(g) and the description thereof are substantially the same as that of the FIGS. 3(g) to 3(h) of the second embodiment. Specifically, in the present embodiment, few patterned banks 130b would remain between the height auxiliary structure 141 and the thin film transistor TFT. At least a portion of the pixel electrode 150 is disposed on the patterned banks 130b.

As a result, the liquid crystal display panel Cell of the present embodiment comprises the base 110, the scan line 111, the capacitor 113, the data line 112, the thin film transistor TFT and the passivation 120 on the base 110. The color filter layers 140 are in the pixel regions P. The pixel electrode 150 is disposed on the color filter layers 140. The pixel electrode 150 is electrically connected with the drain D of the thin film transistor TFT via the contact hole Via and is disposed in the pixel region P correspondingly. The pixel electrode 150 and the capacitor electrode 113 form the storage capacitor. The height auxiliary structure 141 is formed on the thin film transistor TFT. The top view of the height auxiliary structure 141 has a circle, a circle-like shape or an irregular compact pattern. The irregular compact pattern may be an irregular compact pattern without any acute angle or an irregular compact pattern without any right angle. The height auxiliary structure 141 has an average thickness of about 0.01 micrometer to 2 micrometers. The height auxiliary structure 141 has an average width of about 1 micrometer to 100 micrometers. The material of the height auxiliary structure 141 includes a thermal sensitive or photosensitive material. The material of the height auxiliary structure 141 comprises a dye, pigment or a combination thereof. The opposite substrate 20 may comprise a plurality of the spacers 230. At least one of the spacers 230 overlaps with at least a part of the height auxiliary structure 141 or completely on the height auxiliary structure 141. The liquid crystal layer 30 is formed between the active array substrate 10 and the opposite substrate 20. The opposite substrate 20 comprises the base 210 and the common electrode 220 on the base 210. The height auxiliary structure 141 can be disposed on, and preferable aligned with the thin film transistor TFT. However, depending on the design or demand, the height auxiliary structure 141 can be disposed on, and preferable aligned with the data line 112, the scan line 111 or in the pixel regions P.

Unlike the second embodiment, the patterned banks 130b remain, so the step of removing the patterned banks 130b is omitted.

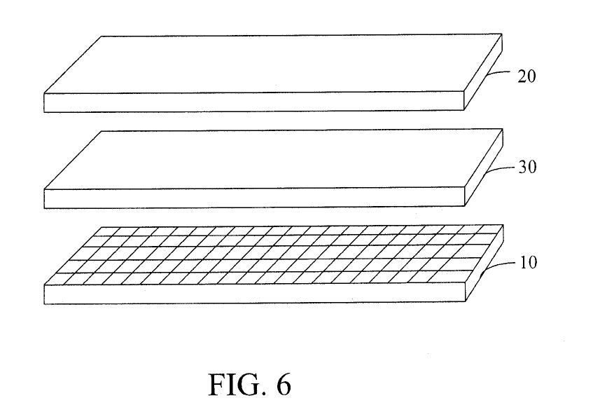

FIG. 6 illustrates the liquid crystal display panel Cell manufactured according to the present embodiment of the present invention. The liquid crystal display panel Cell comprises the active array substrate 10 of the present embodiment of the present invention, the opposite substrate 20 and the liquid crystal layer 30 disposed therebetween.

With reference to FIGS. 7(a) to 7(d), the location, shape, size and manufacturing method of the height auxiliary structure 141 are not limited to the embodiments of the present invention. Designers and engineers can change and adjust the requirements as needed.

It will be apparent to those skilled in the art that various modifications and variations can be made to the structure of the present invention without departing from the scope or spirit of the invention. In view of the foregoing, the present invention covers the modifications and variations of this invention provided they fall within the scope of the following claims and their equivalents.

What is claimed is:

1. A method for manufacturing an active array substrate, comprising:
providing a base;
forming a scan line, a data line and an active device on the base;
forming a photoresist layer on the scan line, the data line and the active device;
patterning the photoresist layer to form at least one patterned bank, wherein the at least one patterned bank forms at least one pixel region;
providing fluid color material in the pixel region;
curing the fluid color material to form a plurality of color filter layers;
forming a pixel electrode electrically connected with the active device and in the pixel region; and
forming a height auxiliary structure having a curved top surface by ink jet printing on the active device, the data line or the scan line.

2. The method according to claim 1, further comprising forming a passivation on the active device before the step of forming the photoresist layer on the scan line, the data line and the active device.

3. The method according to claim 2, wherein the step of patterning the photoresist layer comprises:
providing a mask over the photoresist layer;
exposing and the photoresist layer by the mask;
removing a portion of the photoresist layer to form the at least one patterned bank; and
etching the passivation to form a contact hole, wherein the pixel electrode is electrically connected with the active device via the contact hole.

4. The method according to claim 3, wherein the mask comprises a half-tone mask or a grey-tone mask.

5. The method according to claim 1, wherein the photoresist layer has an average thickness of about 0.5 micrometers to 5 micrometers.

6. The method according to claim 1, wherein at least one capacitor region is formed between the patterned banks and the pixel electrode is further located in the capacitor region, the method further comprising:
forming a capacitor electrode on the base and in the capacitor region, wherein the capacitor electrode and the pixel electrode form a storage capacitor.

7. The method according to claim 1, further comprising at least a portion of the patterned bank to form a capacitor region.

8. The method according to claim 1, wherein the step of forming the height auxiliary structure comprises:
providing the fluid color material on the active device, the data line or the scan line by ink jet printing; and
curing the fluid color material.

9. The method according to claim 1, wherein the pixel electrode is formed on the color filter layer and the patterned bank.

10. The method according to claim 1, wherein the height auxiliary structure and the plurality of color filter layers are formed by ink jet printing simultaneously.

11. A method for manufacturing a liquid crystal display panel, comprising:
forming an active array substrate, comprising:
providing a base;
forming a scan line, a data line and an active device on the base;
forming a photoresist layer on the scan line, the data line and the active device;
patterning the photoresist layer to form at least one patterned bank, wherein the at least one patterned bank forms at least one pixel region;
providing fluid color material in the pixel region;
curing the fluid color material to form a plurality of color filter layers;
forming a pixel electrode electrically connected with the active device and in the pixel region; and
forming a height auxiliary structure by ink jet printing on the active device, the data line or the scan line, the height auxiliary structure having a curved top surface;
forming an opposite substrate comprising a plurality of spacers, wherein one of the spacers is overlapped with the height auxiliary structure; and
forming a liquid crystal layer between the active array substrate and the opposite substrate.
